(19) United States
(12) Patent Application Publication
(10) Pub. No.: US 2026/0305453 A1
(43) Pub. Date: Oct. 1, 2026

(54) MULTI-LAYER METAL STACK FOR WIRE BONDING

(71) Applicant: TEXAS INSTRUMENTS INCORPORATED, DALLAS, TX (US)

(72) Inventors: Jeffrey SOLAS, ILOILO CITY (PH); Jomari AUSTRIA, MABALACAT CITY (PH); Jose Arvin PLOMANTES, DAGUPAN (PH)

(21) Appl. No.: 19/093,644

(22) Filed: Mar. 28, 2025

(51) Int. Cl. H10W 74/10; H10W 40/10; H10W 70/40; H10W 72/00; H10W 72/20; H10W 72/29; H10W 72/59; H10W 72/90; H10W 90/00

(52) U.S. Cl. CPC H10W 74/121; H10W 40/10; H10W 70/40; H10W 72/01235; H10W 72/01935; H10W 72/01955; H10W 72/222; H10W 72/29; H10W 72/59; H10W 72/859; H10W 72/923; H10W 72/936; H10W 72/9415; H10W 72/952; H10W 90/726; H10W 90/753

(57) ABSTRACT

An electronic device is provided that includes a substrate and a die disposed on a first surface of the substrate, where the die includes contact pads embedded in an active surface of the die. A protective element is disposed on one or more of the contact pads and interconnects are disposed on one or more different contact pads of the contact pads. A dielectric layer is disposed on the active surface of the die and wire bonds are attached from the protective element to one or more other electronic components in the electronic device. A leadframe is attached to the interconnects and a mold compound formed over the die.

### TECHNICAL FIELD

The present disclosure relates to an electronic device and more specifically, to an integrated circuit package having a multi-layer metal stack disposed on a metal contact pad for wire bonding.

### BACKGROUND

Titanium is commonly used as a seed and/or barrier layer when depositing copper (e.g., copper pillar, copper ball, etc.) on a metal contact pad (e.g., aluminum pad) in an integrated circuit. The titanium layer provides good adhesion between the copper pillar and the contact pad thereby improving the reliability of the joint. In addition, titanium is thermally stable and thus can withstand high temperatures during processing. Further, the titanium layer acts as a barrier to prevent copper diffusion (Intermetallic Compound (IMC) formation) into the contact pad during high-temperature processes, such as solder reflow. Still further, the titanium layer has low electrical resistivity, which is beneficial for good electrical conductivity.

### SUMMARY

In described examples, an electronic device includes a leadframe and a die assembly attached to the leadframe, where the die assembly includes contact pads and a protective element disposed on one or more of the contact pads. A wire bond is attached from the protective element to one or more other electronic components in the electronic device and a mold compound formed over the die assembly.

In another described example, an electronic device includes a substrate and a die disposed on a first surface of the substrate, where the die includes contact pads embedded in an active surface of the die. A protective element is disposed on one or more of the contact pads and interconnects are disposed on one or more different contact pads of the contact pads. A dielectric layer is disposed on the active surface of the die and wire bonds are attached from the protective element to one or more other electronic components in the electronic device. A leadframe is attached to the interconnects and a mold compound formed over the die.

In still another described example, a method includes attaching a die to a first surface of a substrate, where the die has an active surface and contact pads embedded in the active surface of the die. A protective element is deposited on one or more of the contact pads and a dielectric layer is deposited on the active surface of the die. A seed layer is deposited on the dielectric layer. An etching process is performed to remove the seed layer from unwanted portions of the dielectric layer. Interconnects are deposited to one or more different contact pads of the contact pads. A leadframe is attached to the interconnects and a mold compound is formed over the die.

### BRIEF DESCRIPTION OF THE DRAWINGS

FIG. 1A is a cross section view of an example electronic device that includes a multi-layer metal stack.

FIG. 1B is a cross section view of an alternative example electronic device devoid of the multi-layer metal stack.

FIG. 2 is a block diagram illustration of a method of fabricating the electronic device of FIG. 1A.

FIG. 3A is a top view of a substrate array (wafer).

FIG. 3B illustrates a cross section view of a singulated substrate chip (hereinafter “substrate”) from the substrate array in FIG. 3A in the early stages of fabrication of an electronic device.

FIG. 3C illustrates a cross section view of the electronic device in FIG. 3B that includes a die disposed on a surface of the substrate.

FIG. 3D illustrates a cross section view of the electronic device in FIG. 3C after undergoing deposition of a first metal layer on an active surface of the die.

FIG. 3E illustrates a cross section view of the electronic device of FIG. 3D after undergoing a first photoresist material layer patterning..

FIG. 3F illustrates a side view of the electronic device of FIG. 3E after undergoing a first plating process.

FIG. 3G illustrates a side view of the electronic device of FIG. 3F after undergoing a second plating process.

FIG. 3H illustrates a side view of the electronic device of FIG. 3G after removal of the first photoresist material layer.

FIG. 3I illustrates a side view of the electronic device of FIG. 3H after undergoing a first etching process to remove the first metal layer from unwanted portions of the die.

FIG. 3J illustrates a side view of the electronic device of FIG. 3I after undergoing deposition of a dielectric layer on the die.

FIG. 3K illustrates a cross section view of the electronic device in FIG. 3J after undergoing deposition of a fourth metal layer on a surface of the dielectric layer.

FIG. 3L illustrates a cross section view of the electronic device of FIG. 3K after undergoing a second photoresist material layer patterning.

FIG. 3M illustrates a side view of the electronic device of FIG. 3L after undergoing a third plating process.

FIG. 3N illustrates a side view of the electronic device of FIG. 3M after removal of the second photoresist material layer.

FIG. 3O illustrates a side view of the electronic device of FIG. 3N after undergoing a second etching process to remove the fourth metal layer from unwanted portions of the dielectric layer.

FIG. 3P illustrates a cross section view of the electronic device of FIG. 3O after deposition of solder balls on interconnects.

FIG. 3Q illustrates a side view of the electronic device of FIG. 3P after attachment to a leadframe.

FIG. 3R illustrates a side view of the electronic device of FIG. 3Q after undergoing attachment of wire bonds.

FIG. 3S illustrates a side view of the electronic device of FIG. 3R after attachment of a heat sink to the substrate.

FIG. 3T illustrates a side view of the electronic device of FIG. 3S after formation of a mold compound.

### DETAILED DESCRIPTION

Titanium can be used as a seed and/or barrier layer when depositing copper (e.g., copper pillar, copper ball, etc.) on metal (e.g., aluminum) contact pads in an integrated circuit. The titanium layer provides good adhesion between the copper pillar and the contact pad thereby improving the reliability of the joint. In addition, titanium is thermally stable and thus can withstand high temperatures during processing. Further, the titanium layer acts as a barrier to prevent copper diffusion (Intermetallic Compound (IMC) formation) into the contact pad during high-temperature processes, such as solder reflow. Still further, the titanium layer has low electrical resistivity, which is beneficial for good electrical conductivity.

During downstream processing, however, removal of the titanium layer on unwanted portions of the integrated circuit causes damage to those portions. Specifically, the titanium layer is removed with hydrofluoric acid during an etching process. During the etching process, the hydrofluoric acid chemically attacks the metal contact pads (e.g., aluminum pad) that are subject to receiving wire bonds and leaves fluorine residues on the metal contact pads. As a result, the damaged metal contact pads leads to poor adhesion of the wire bond during a wire bonding process thereby compromising the performance of the electronic device.

Disclosed herein is an electronic device (e.g., integrated circuit (IC)) and method of fabricating the electronic device that overcomes the aforementioned disadvantages. The electronic device includes a metal stack comprising multiple metal layers that are deposited on the metal contact pads. Specifically, the multi-layer metal stack are deposited on the metal contact pads that are to receive a wire bond. The multi-layer metal stack protects the wire bond metal contact pads during fabrication of the electronic device. The multi-layer metal stack is an extension of the wire bond metal contact pads and is thus configured to receive the wire bond. The multi-layer metal stack comprises a first metal (e.g., titanium) layer, a second metal (e.g., nickel) layer, and a third metal (e.g., palladium) layer.

During fabrication of the electronic device, the first metal layer is deposited on an active surface of a die, including any metal contact pads embedded in the active surface of the die. The first metal layer is a seed layer to facilitate adhesion of subsequent metal layers deposited to the metal contact pads. The second and third metal layers of the multi-layer metal stack are subsequently deposited on a portion of the first metal layer that covers only the wire bond metal contact pads. A first etching process is performed to remove the first metal layer from unwanted portions of the active surface of the die including from metal contact pads that do not receive wire bonds. After deposition of a dielectric layer, a fourth (e.g., second titanium layer) layer is deposited over the dielectric layer, the multi-layer metal stack, and any other exposed contact pads not subject to wire bonding. Metal (e.g., copper) pillars are deposited on the other exposed contact pads and a second etching process is performed to remove the remaining fourth metal layer from the unwanted portions of the dielectric layer and the multi-layer metal stack. Hydrofluoric acid is used to remove the first and fourth metal layers (e.g., first and second titanium layers) during the first and second etching processes respectively. The presence of the multi-layer metal stack, however, ensures that the wire bond contact pads are protected and undamaged during the first and second etching process. Thus, the wire bonds can be indirectly attached to wire bond contact pads via the multi-layer metal stack without compromising performance of the electronic device.

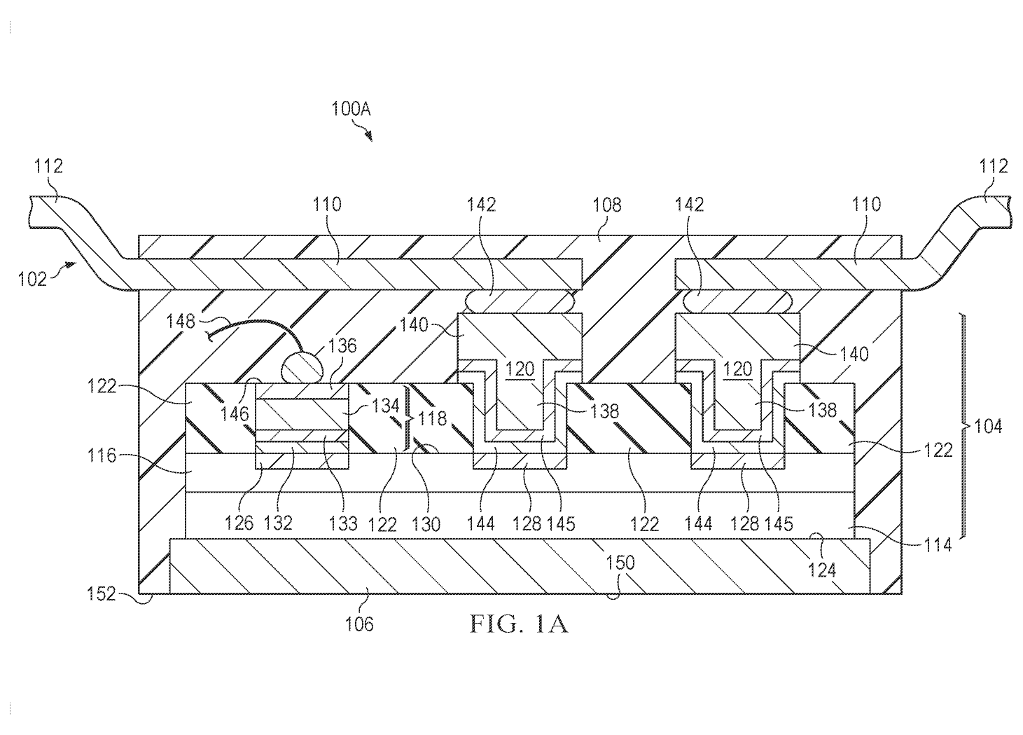

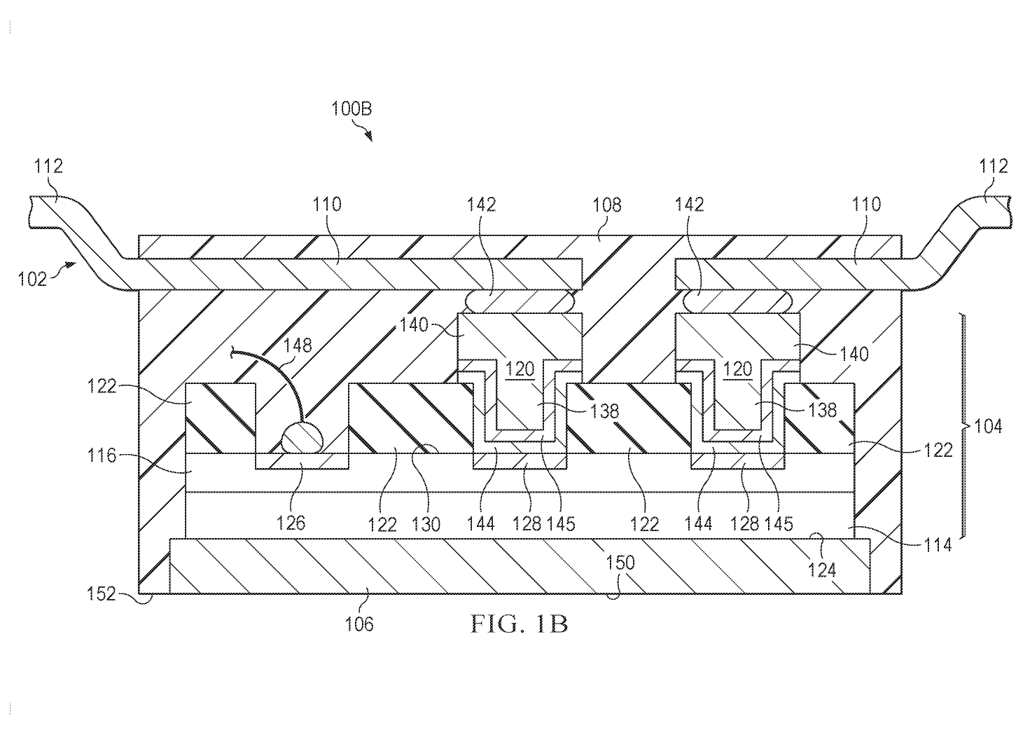

FIG. 1A is a cross-sectional view of an example electronic device (e.g., integrated circuit (IC)) 100A that includes a multi-layer metal stack configured to provide protection to one or more metal contact pads during fabrication. Although, the example electronic device 100A described herein and illustrated in FIG. 1A is a leaded package, the electronic device 100A can be comprised of any type of leaded IC package including, but not limited to a small outline transistor (SOT), a small outline IC (SOIC), a dual in-line package (DIP), etc. or a non-leaded IC package including, but not limited to a land grid array (LGA), a quad-flat package (QFP), a quad-flat no-lead (QFN), etc., as well as LFPAK, TOLT, and TOLG packages. Thus, the example electronic device 100A illustrated in FIG. 1A is for illustrative purposes only and is not intended to limit the scope of the invention.

The electronic device 100A includes a leadframe 102, a die assembly 104 attached to a heat sink 106, and a mold compound 108. The leadframe 102 includes inner (internal) leads 110 disposed inside the mold compound 108 and outer (external) leads 112 disposed outside the mold compound 108. The die assembly 104 is comprised of a substrate (e.g., silicon wafer) 114, a die 116, a multi-layer metal stack 118, interconnects (e.g., copper pillars) 120, and a dielectric layer 122.

The substrate 114 is disposed on a first surface 124 of the heat sink 106 and the die 116 is disposed on a surface of the substrate 114. Metal contact pads comprised of wire bond contact pads 126 and interconnect contact pads 128 are embedded in an active surface 130 of the die 116 such that an exposed surface of the contact pads 126, 128 are substantially flush with the active surface 130 of the die 116. The wire bond contact pads 126 are configured to receive wire bonds and the interconnect contact pads 128 are configured to receive the interconnects 120. The number of wire bond contact pads 126 and interconnect contact pads 128 may vary based on the application of the electronic device 100A. For simplicity, one wire bond contact pad 126 and two interconnect contact pads 128 are illustrated in FIG. 1A. Thus, the electronic device illustrated in FIG. 1A is for illustrative purposes only and is not intended to limit the scope of the invention.

The multi-layer stack 118 is disposed on one or more of the wire bond contact pads 126. The multi-layer metal stack 118 is comprised of a seed layer or first metal layer and includes a first metal (e.g., titanium) sub-layer 132 and a second metal (e.g., copper) sub-layer 133. The multi-layer stack 118 further includes a second metal (e.g., nickel) layer 134 disposed on the first metal layer 132, 133, and a third metal (e.g., palladium) layer 136 disposed on the second metal layer 134. The first metal layer 132, 133 is disposed on each of the one or more wire bond contact pads 126 and is provided as the seed layer to facilitate adhesion of the subsequent second and third metal layers 134, 136. The multi-layer stack 118 is configured to provide protection to each of the wire bond contact pads 126 during chemical etching processes, as explained above and as will be described further below. Thus, the multi-layer metal stack 118 is a protective element configured to protect each of the wire bond contact pads 126 from the chemical etching process.

The interconnects 120 are disposed on one or more interconnect contact pads 128 and provide a connection between the die 116 and the leadframe 102. Specifically, a base portion 138 of the interconnects 120 attaches to the interconnect contact pads 128 and an attachment portion 140 of the interconnects 120 is connected to the inner leads 110 of the lead frame 102 via solder interconnects 142. A second seed layer or fourth metal layer comprising a third metal (e.g., titanium) sub-layer 144 and a fourth metal (e.g., copper) sub-layer 145 is disposed between the interconnects 120 and the interconnect contact pads 128. The fourth metal layer 144 facilitates adhesion of the deposition of the interconnects 120. The dielectric layer 122 is disposed on the active surface 130 of the die 116 such that the multi-layer metal stack 118 and the base portion 138 of the interconnects 120 are embedded in the dielectric layer 122. A surface 146 of the palladium layer 136 is substantially flush with a surface of the dielectric layer 122 and is thus exposed to receive a wire bond 148. Although not illustrated, the wire bond 148 connects to either another die (e.g., controller die) or an inner lead 110 in the electronic device 100A.

The mold compound 108 encapsulates the die assembly 104, the inner leads, and the wire bond 148. The mold compound 108 encapsulates the inner leads 110, the substrate 114, the die 116, the multi-layer metal stack 118, the interconnects 120, the dielectric layer 122, the contact pads 126, 128, and the wire bonds 148. A second surface (exposed surface) 150 of the heat sink 106 is exposed and substantially flush with a surface 152 of the mold compound 108. Thus, the mold compound 108 covers all but one surface of the heat sink 106, where the one surface is the exposed surface 150, where the exposed surface 150 faces away from the die 116. The second surface 150 attaches to an external electrical/electronic device (e.g., heat sink) to dissipate heat away from the electronic device 100A.

FIG. 1B is a cross-sectional view of another example electronic device (e.g., integrated circuit (IC)) 100B. The example electronic device 100B illustrated in FIG. 1B is similar to the electronic device 100A illustrated in FIG. 1A with the exception of the metal stack 118. In other words, the example electronic device 100B illustrated in FIG. 1B does not include the multi-layer metal stack 118 comprised of the first metal layer 132, 133 the second metal layer 134, and the third metal layer 136 illustrated in the electronic device 100A in FIG. 1A.

Thus, during fabrication of the electronic device 100B, since the electronic device 100B does not include the multi-layer metal stack, during an etching process to remove the fourth metal layer 144 from the dielectric layer 122, the hydrofluoric acid damages the exposed wire bond contact pads 126. Thus, bonding the wire bonds 148 to the wire bond contact pads 126 becomes problematic since the wire bond contact pads 126 are damaged. As a result, electrical performance of the electronic device 100B is compromised.

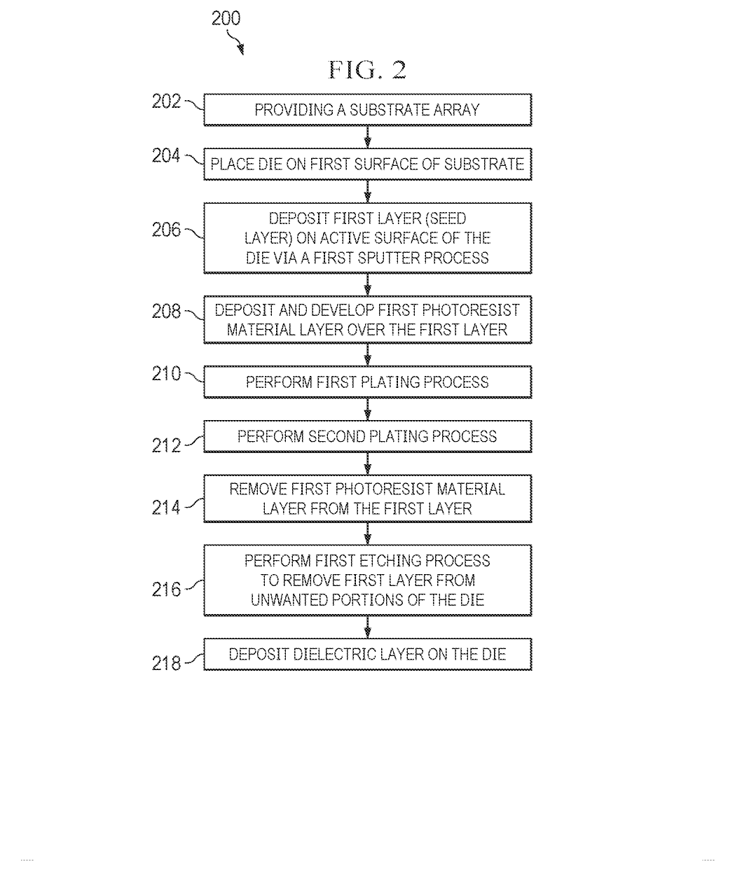

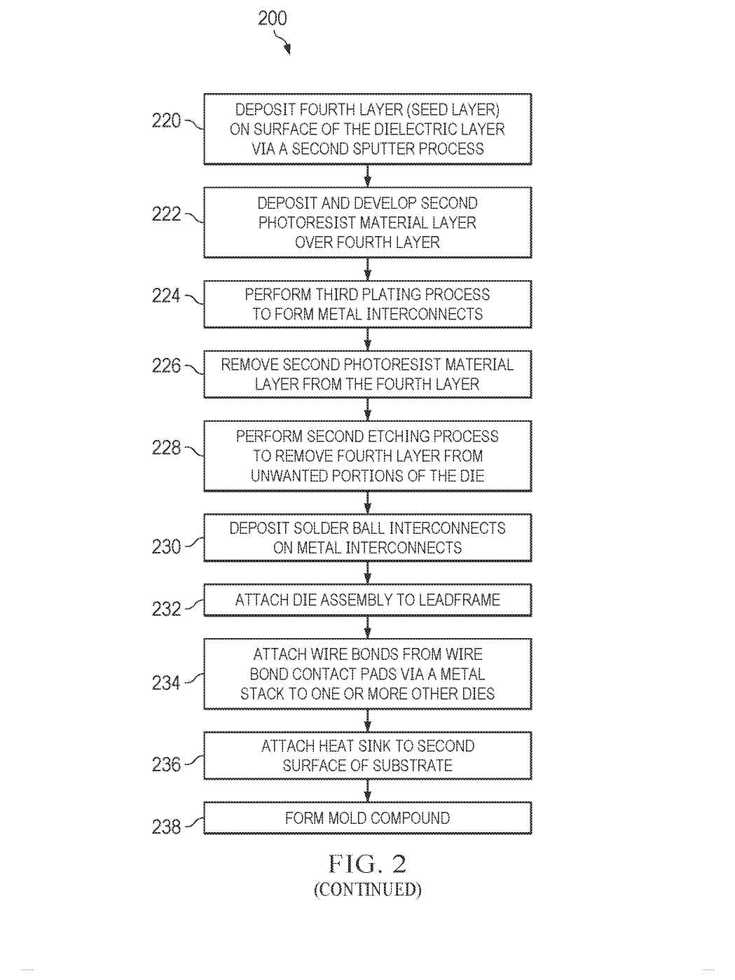

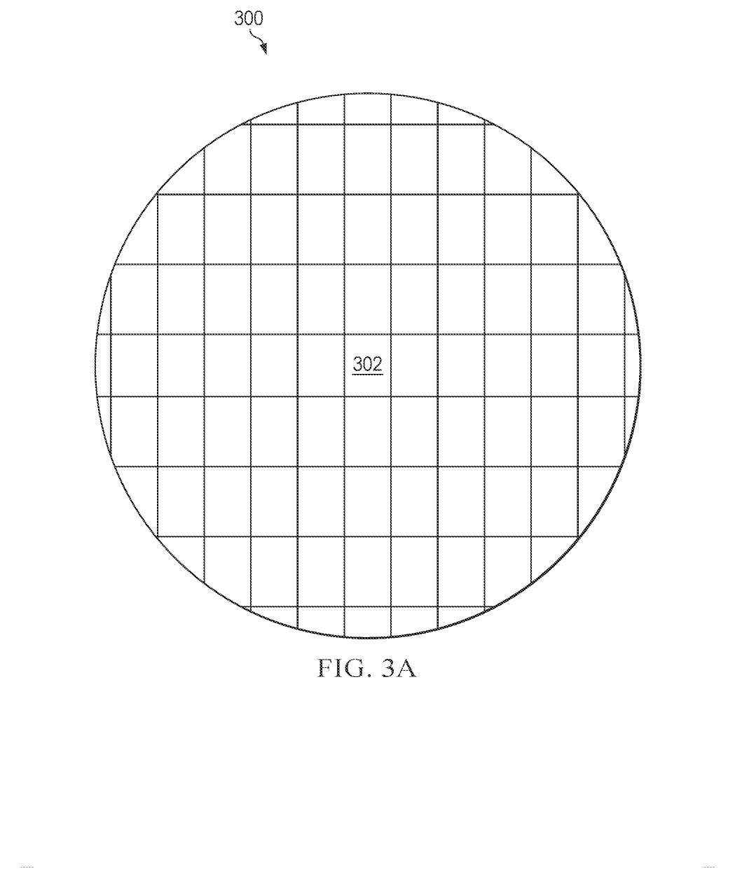

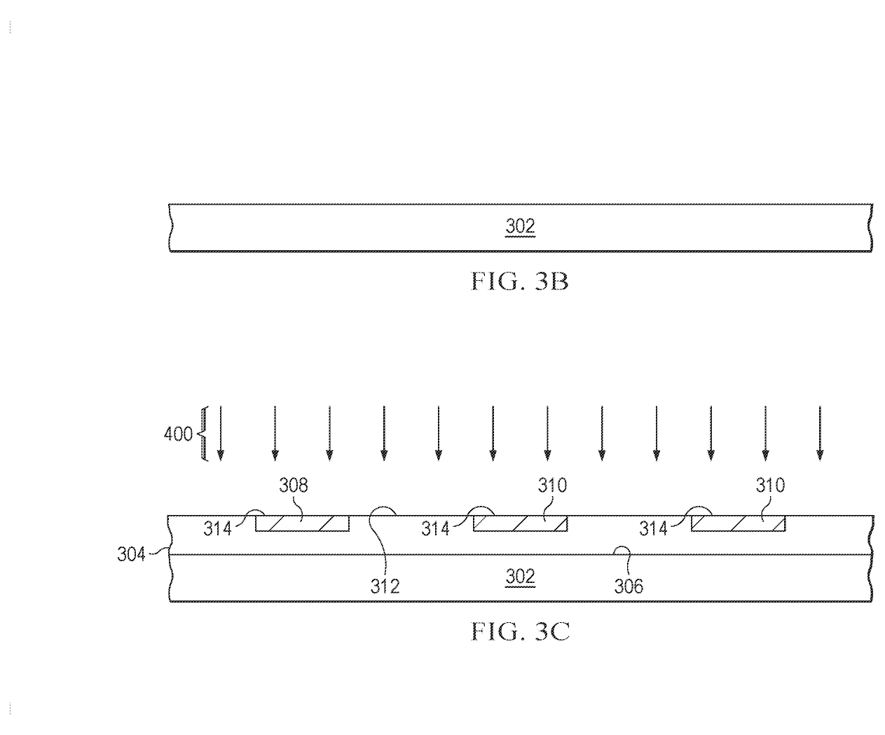

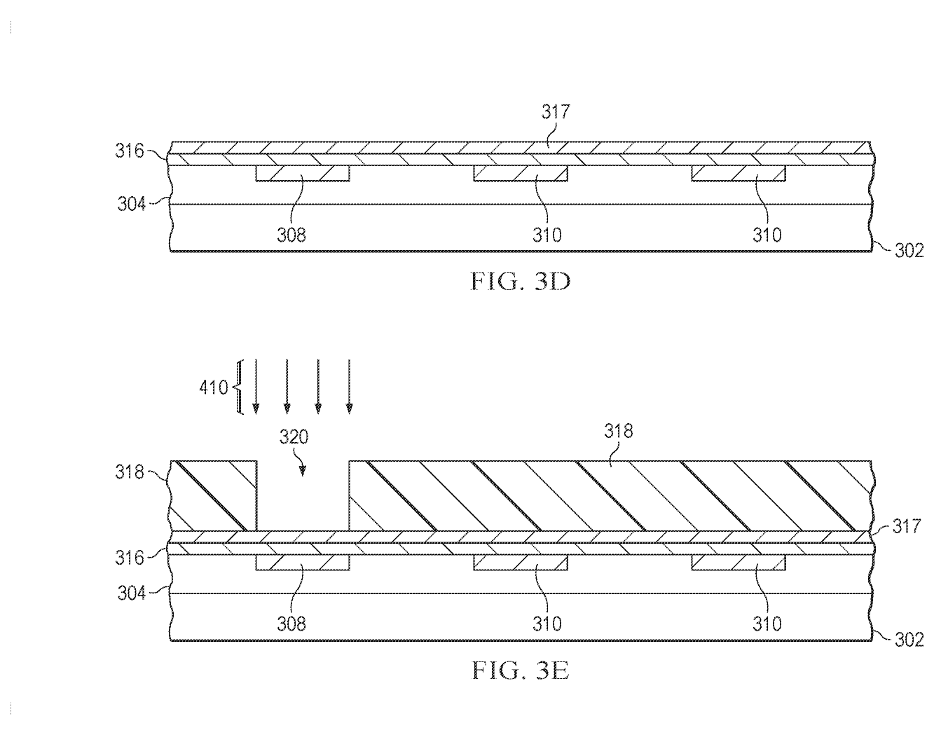

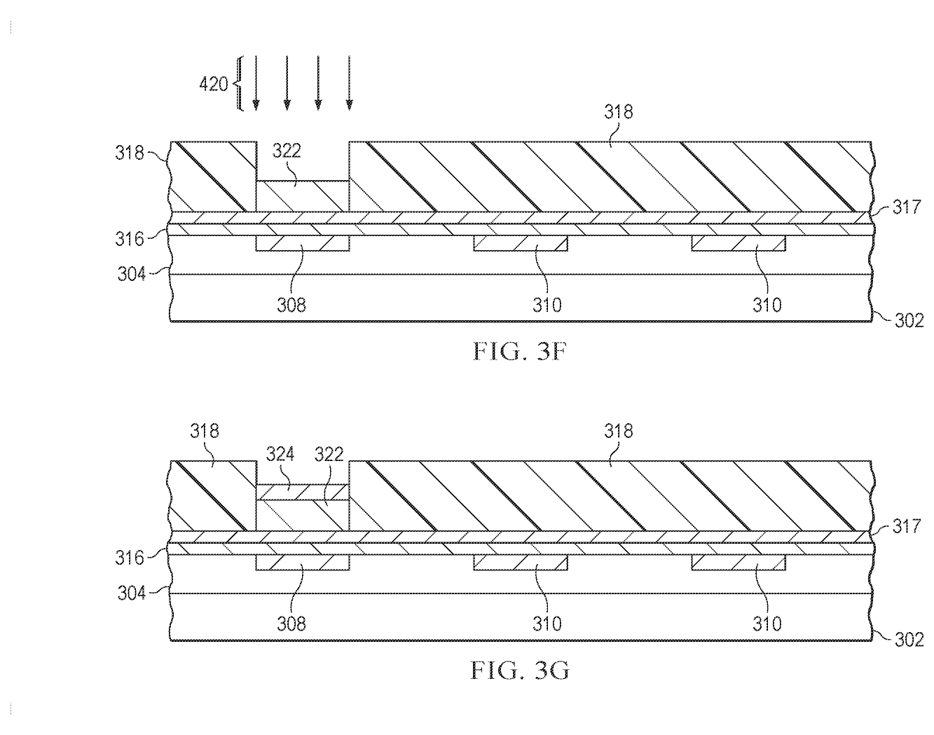

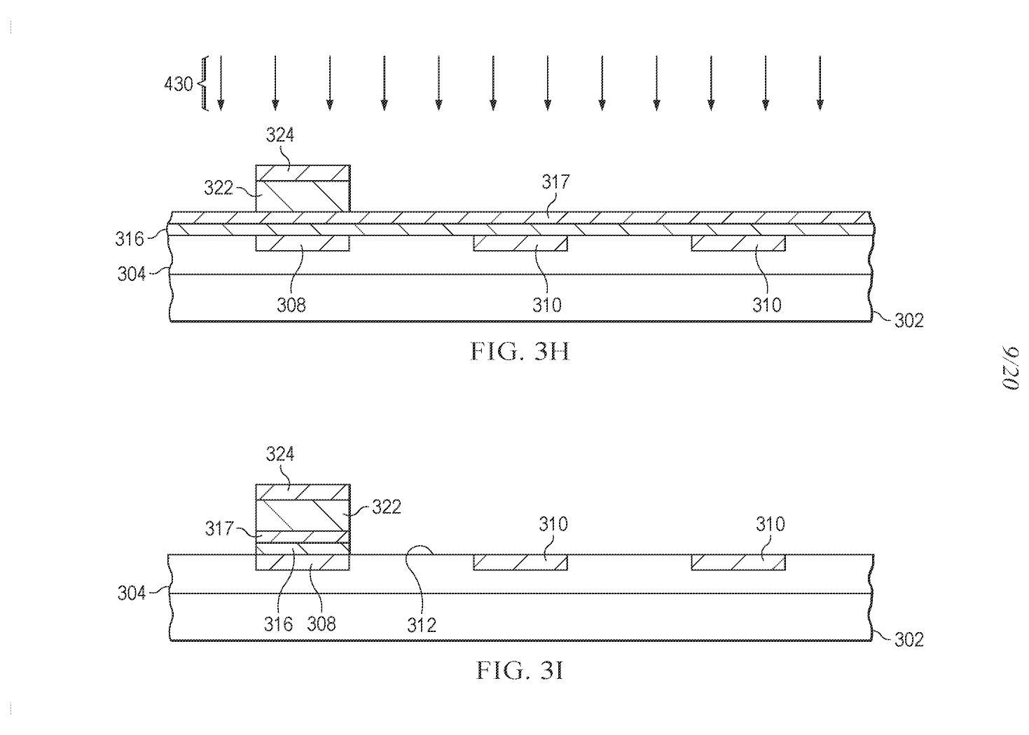

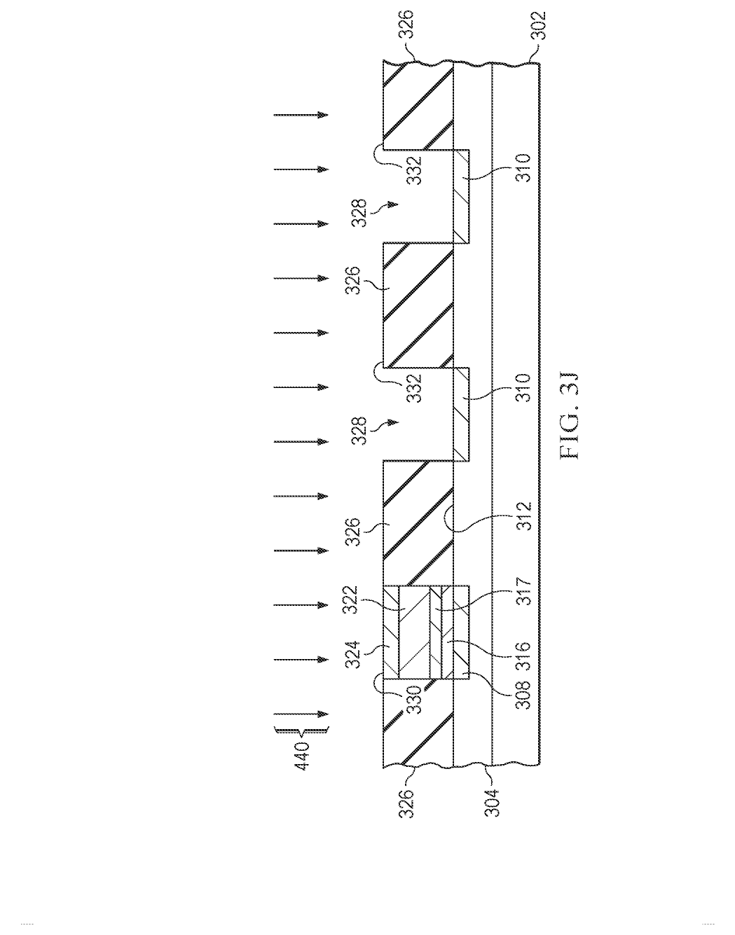

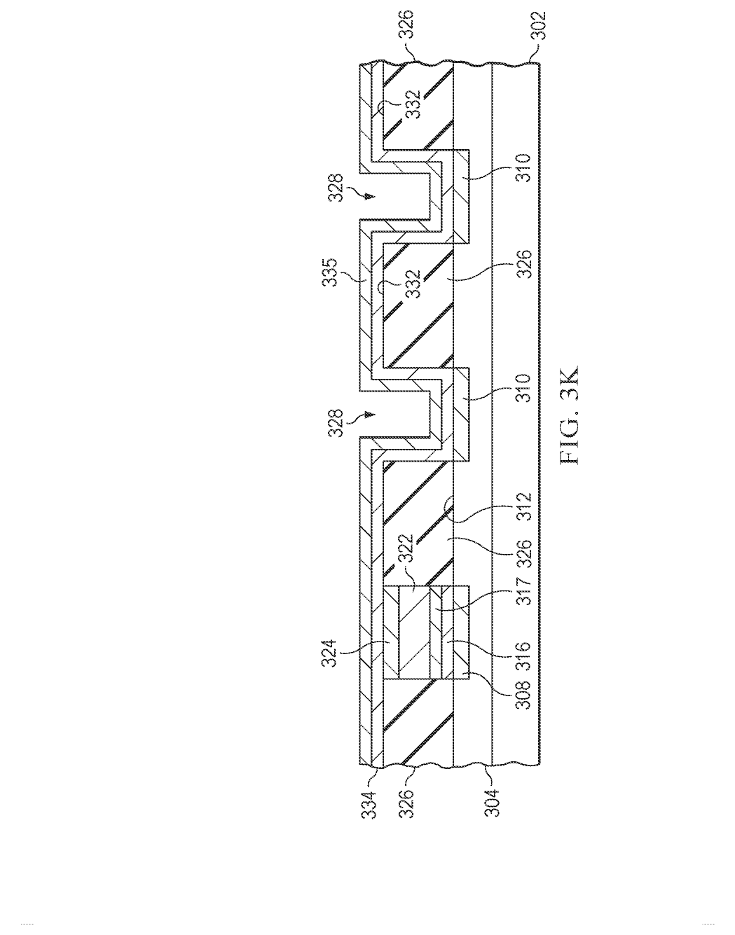

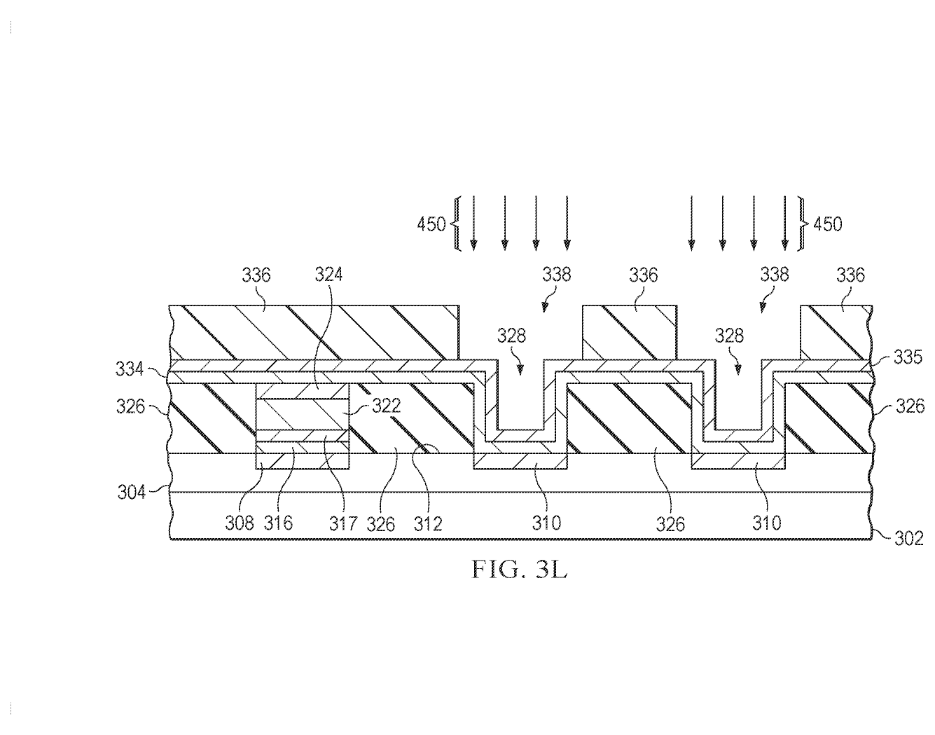

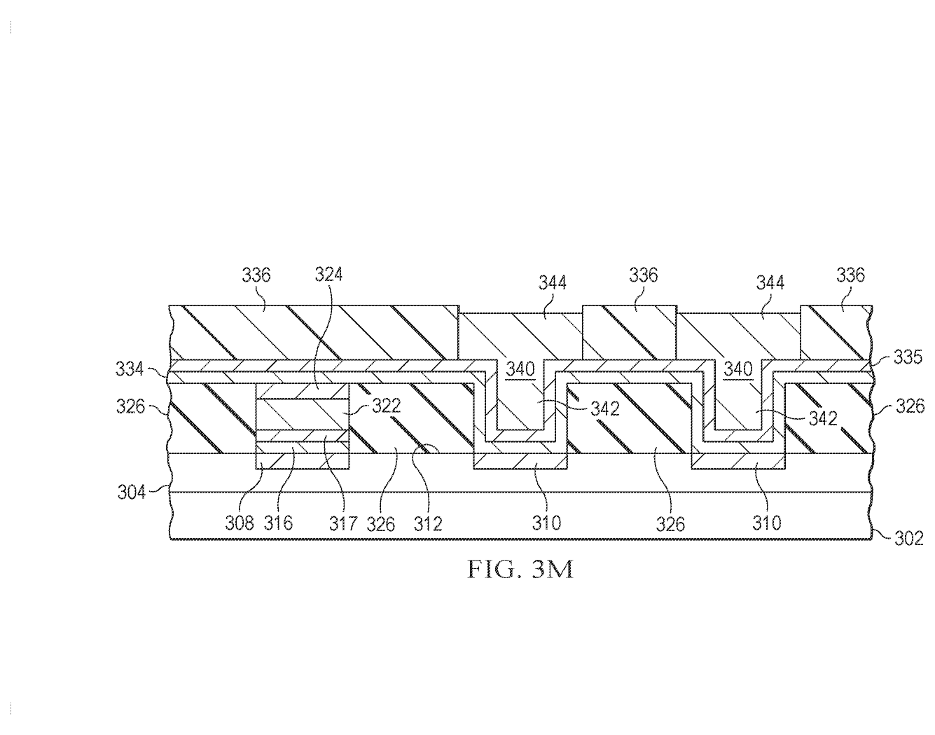

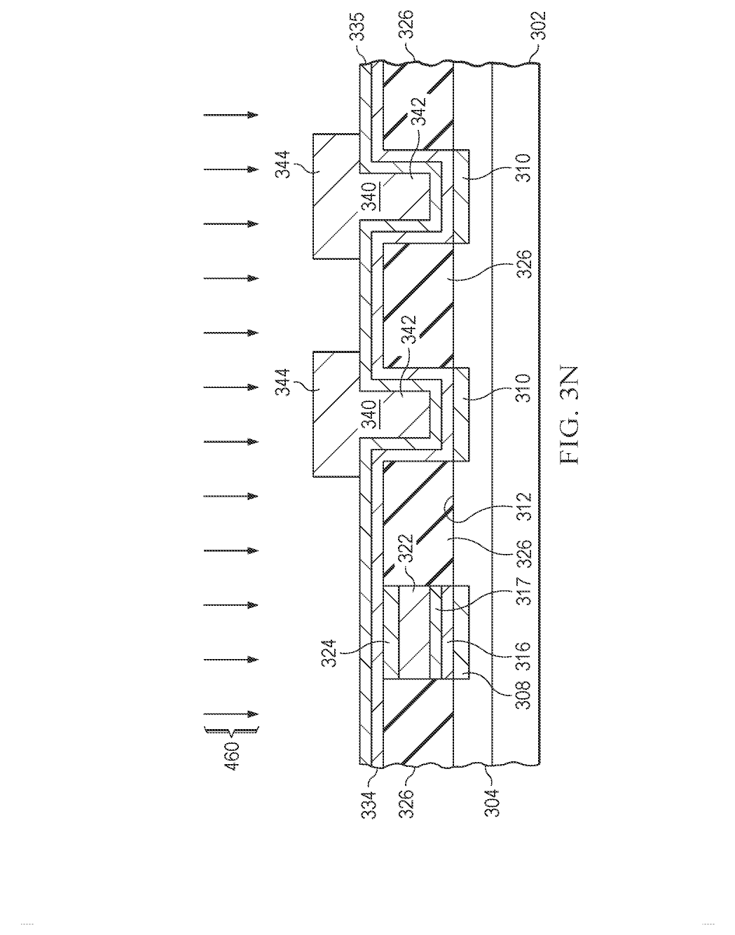

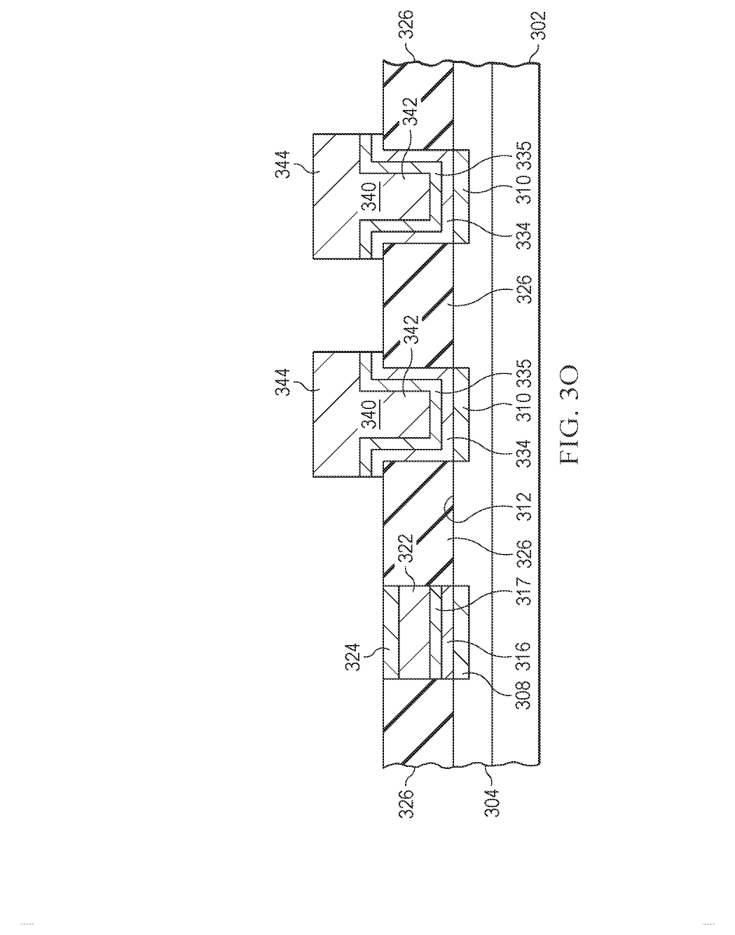

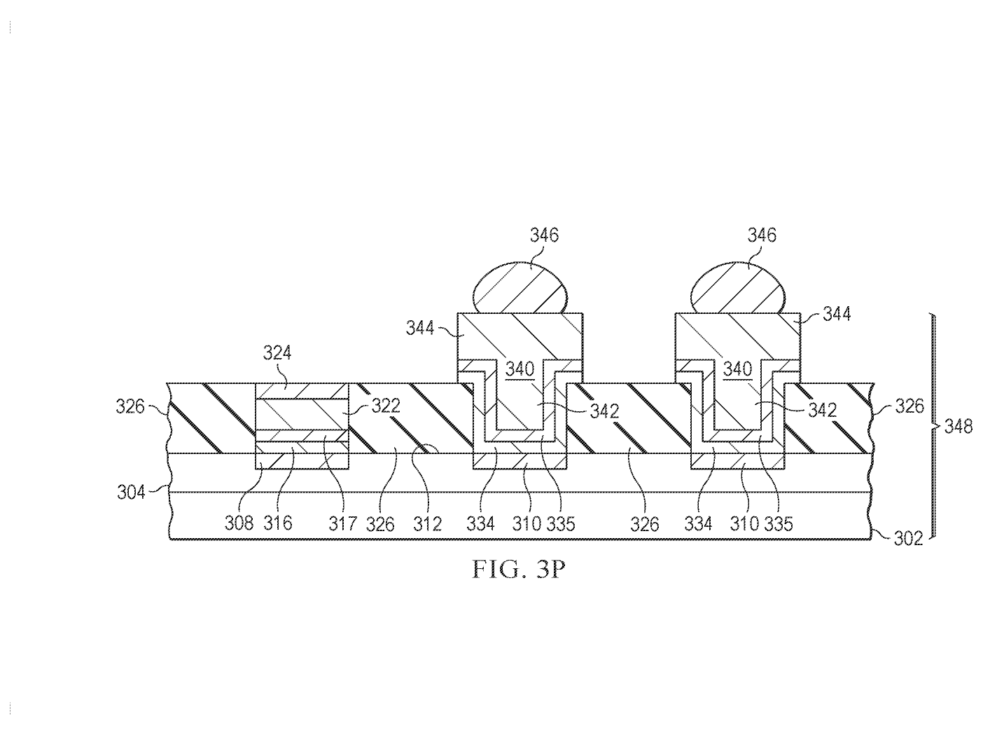

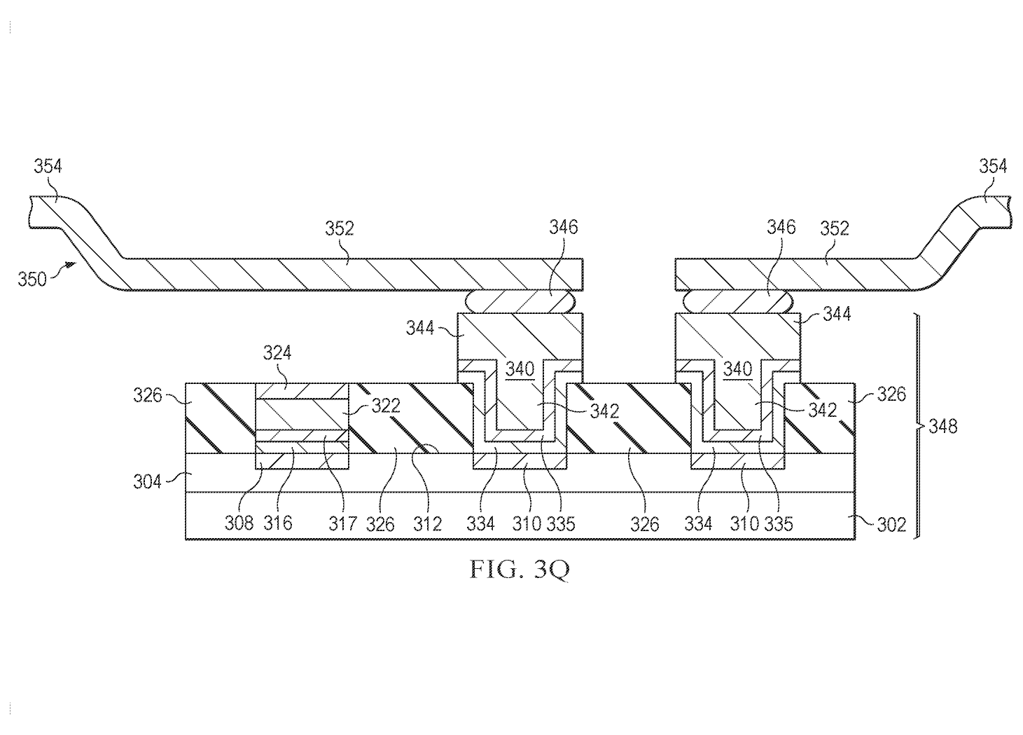

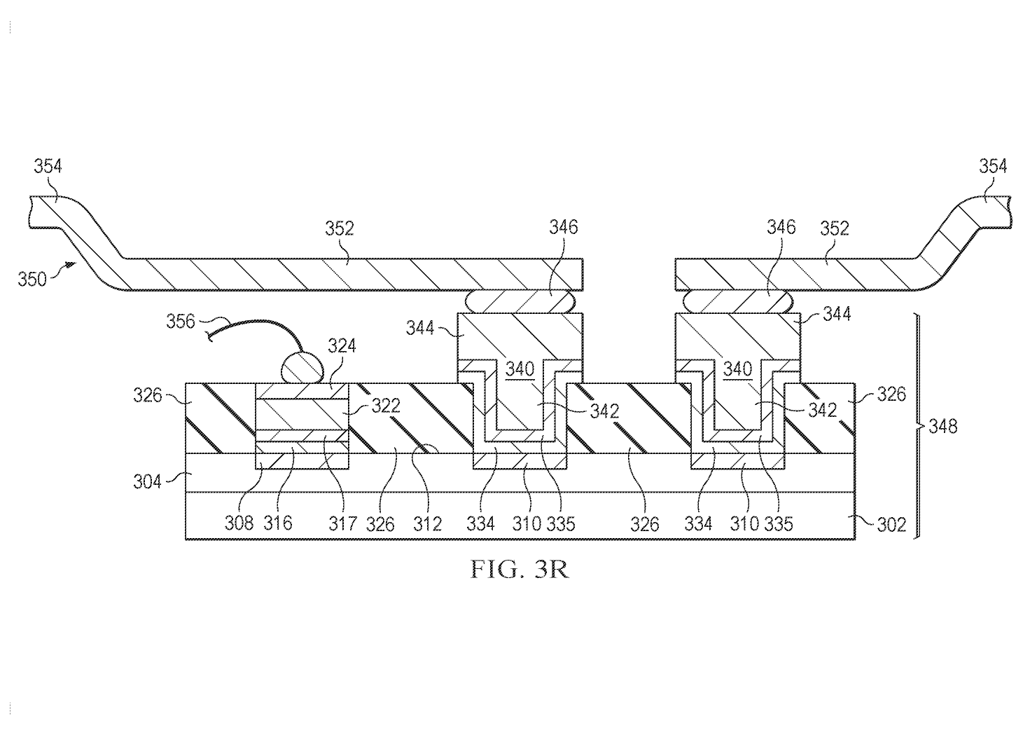

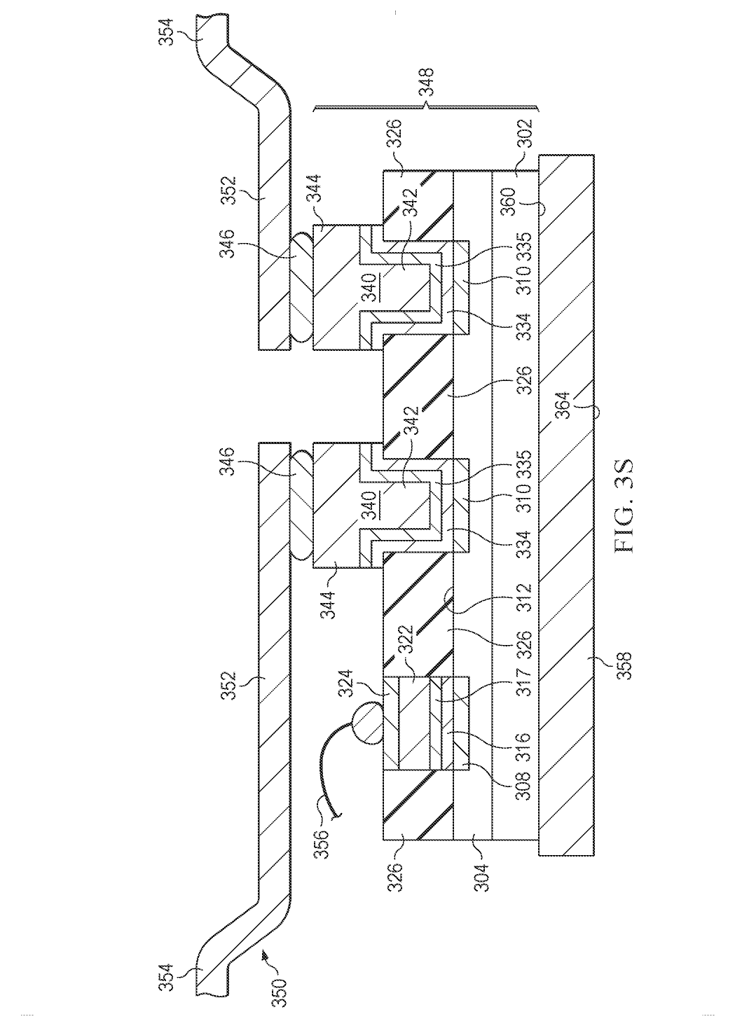

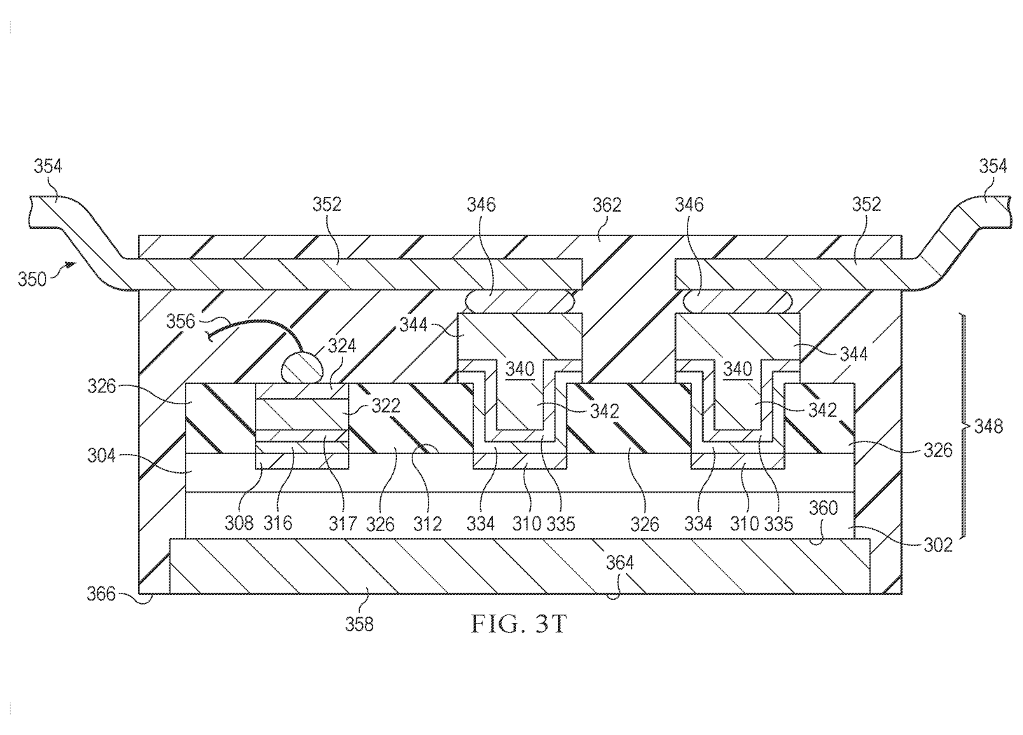

FIGS. 2 and 3A-3T illustrate a fabrication process associated with the fabrication of the electronic device 100A illustrated in FIG. 1A. Specifically, FIG. 2 is a block diagram explanation of the fabrication process steps 200 and FIGS. 3A-3P illustrate the fabrication process associated with the formation of the electronic device 100A illustrated in FIG. 1A. Though depicted sequentially as a matter of convenience, at least some of the actions shown can be performed in a different order and/or performed in parallel. Alternatively, some implementations may perform only some of the actions shown. Still further, although the example illustrated in FIGS. 2 and 3A-3T is an example method illustrating the example configuration of FIG. 1A, other methods and configurations are possible. It is understood that although the method illustrated in FIGS. 2 and 3A-3T depicts the fabrication process of a single electronic device, the process applies to an array of electronic devices. Thus, after fabrication of the array of electronic devices the array is singulated to separate each electronic device 100A from the array.

Referring to FIGS. 2 and 3A-3T, the fabrication process for the electronic device 100A illustrated in FIG. 1A begins at 202 with a substrate array (e.g., wafer) 300, as illustrated in FIG. 3A. Specifically, FIG. 3A is a schematic diagram of a substrate array 300, in accordance with various examples. For example, the substrate array 300 may be a silicon wafer. The manufacturing techniques described below may be performed on individual substrate (wafer) chips 302 (post-singulation), or the techniques may be more efficiently performed on a mass scale, e.g., simultaneously on multiple substrate chips 302 of the substrate array 300 (pre-singulation). For convenience and clarity, the remaining drawings show a single substrate (wafer) chip 302, with the understanding that the processes described herein as being performed on the single substrate chip 302 may also be performed (e.g., sequentially performed, simultaneously performed) on the remaining substrate chips 302 of the substrate array 300.

FIG. 3B illustrates a cross section view of a single substrate chip (hereinafter “substrate”) 302 singulated from the substrate array 300. At 204, a die 304 is deposited on a first surface 306 of the substrate 302 resulting in the configuration of FIG. 3C. The die 304 includes multiple metal contact pads comprising one or more wire bond contact pads 308 and one or more interconnect contact pads 310. The contact pads 308, 310 are embedded in an active surface 312 of the die 304 such that an exposed surface 314 of the contact pads 308, 310 are substantially flush with the active surface 312 of the die 304. The wire bond contact pads 308 are configured to receive wire bonds and the interconnect contact pads 310 are configured to receive interconnects. The number of wire bond contact pads 308 and interconnect contact pads 310 may vary based on the application of the electronic device 100A. For simplicity, one wire bond contact pad 308 and two interconnect contact pads 310 are illustrated in the figures. Thus, the method of fabricating the electronic device illustrated in FIGS. 3A-3T are for illustrative purposes only and is not intended to limit the scope of the invention.

At 206, the configuration of FIG. 3C undergoes a first sputter process 400 to deposit a first metal (first seed) layer comprised of a first metal (e.g., titanium) sub-layer 316, and a second metal (e.g., copper) sub-layer 317 on the active surface 312 of the die 304 such that the first metal layer 316, 317 is also deposited on the exposed surface 314 of each of the contact pads 308, 310 resulting in the configuration of FIG. 3D. Thus, the first sputter process 400 is a two-step sputter process that first deposits the first sub-layer 316 and then subsequently deposits the second sub-layer 317. The first metal layer 316, 317 facilitates adhesion between the wire bond contact pads 308 and subsequent layers that are deposited on the wire bond contact pads 308. The first metal layer 316, 317 has a thickness in a range from approximately 100A to 3000A. At 208, a first photoresist material layer 318 overlies the first metal layer 316, 317 and is patterned and developed to expose first openings 320 in the first photoresist material layer 318 over the wire bond contact pads 308, resulting in the configuration of FIG. 3E. The first photoresist material layer 318 can have a thickness that varies in correspondence with the wavelength of radiation used to pattern the first photoresist material layer 318. The first photoresist material layer 318 may be formed over the first metal layer 316, 317 via spin-coating or spin casting deposition techniques, selectively irradiated (e.g., via deep ultraviolet (DUV) irradiation) and developed to form the first openings 320.

At 210, the configuration of FIG. 3E undergoes a first plating process 410 to deposit a second metal layer (e.g., nickel) 322 on the first metal layer 316, 317 in each opening 320 over each of the wire bond contact pads 308 resulting in the configuration of FIG. 3F. The second metal layer 322 has a thickness in a range from approximately 3um to 10um. At 212, the configuration of FIG. 3F undergoes a second plating process 420 to deposit a third metal layer (e.g., palladium) 324 on the second metal layer 322 in each opening 320 over each of the wire bond contact pads 308 resulting in the configuration of FIG. 3G. The third metal layer 324 has a thickness in a range from approximately 100nm to 300nm. The first, second, and third metal layers 316, 317, 322, 324 form a multi-layer metal stack that is configured to provide protection to each of the wire bond contact pads 308 during downstream etching processes.

At 214, the first photoresist material layer 318 is removed via a first stripping process resulting in the configuration of FIG. 3H. At 216, the configuration of FIG. 3H undergoes a first etching (e.g., chemical etching) process 430 to remove any exposed portions of the first metal layer 316, 317 resulting in the configuration of FIG. 3I. The first etching process 430 uses an acid-based product (e.g., hydrofluoric acid) to remove the exposed portions of the first metal layer 316, 317. The multi-layer metal stack 316, 317, 322, 324, however, protects the wire bond contact pads 308 from the acid-based product during the first etching process 430. Thus, the multi-layer metal stack 316, 317, 322, 324 is a protective element configured to protect each of the wire bond contact pads 308 from the first etching process 430.

At 218, a dielectric (e.g., polyimide) layer 326 is deposited on the active surface 312 of the die 304 resulting in the configuration of FIG. 3J. The dielectric layer 326 is deposited on the active surface 312 of the die 304 such that openings 328 are formed over the each of the interconnect contact pads 310. Thus, the dielectric layer 326 is not deposited on the interconnect contact pads 310. In addition, the dielectric layer 326 surrounds the multi-layer metal stack 316, 317, 322, 324 while leaving a surface 330 of the third metal layer 324 exposed. Thus, the exposed surface 330 of the third metal layer 324 is substantially flush with a surface 332 of the dielectric layer 326.

At 220, the configuration in FIG. 3J undergoes a second sputter process 440 to deposit a fourth metal (second seed) layer comprised of a third metal (e.g., titanium) sub-layer 334, and a fourth metal (e.g., copper) sub-layer 335 on the surface 332 of the dielectric layer 326, on the exposed surface 330 of the third metal layer 324, and on each interconnect contact pad 310 resulting in the configuration of FIG. 3K. Thus, the second sputter process 440 is also two-step sputter process that first deposits the third sub-layer 334 and then subsequently deposits the fourth sub-layer 335. The fourth metal layer 334, 335 facilitates adhesion between the interconnect contact pads 310 and subsequent metal layers/interconnects deposited on the interconnect contact pads 310. The fourth metal layer 334, 335 has a thickness in a range from approximately 100A to 3000A.

At 222, a second photoresist material layer 336 overlies the fourth metal layer 334, 335 and is patterned and developed to expose second openings 338 in the second photoresist material layer 336 over each of the interconnect contact pads 310, resulting in the configuration of FIG. 3L. The second photoresist material layer 336 can have a thickness that varies in correspondence with the wavelength of radiation used to pattern the second photoresist material layer 336. The second photoresist material layer 336 may be formed over the fourth metal layer 334, 335 via spin-coating or spin casting deposition techniques, selectively irradiated (e.g., via deep ultraviolet (DUV) irradiation) and developed to form the second openings 338.

At 224, the configuration in FIG. 3L undergoes a third plating process 450 to deposit metal interconnects (e.g., copper pillars) 340 in the openings 328 of the dielectric layer 326 and in the second openings 338 of the second photoresist material layer 336 resulting in the configuration of FIG. 3M. Specifically, a base portion 342 of the metal interconnects 340 is deposited in the openings 328 of the dielectric layer 326 and an attachment portion 344 of the metal interconnects 340 is deposited in the second openings 338 of the second photoresist material layer 336. Thus, the attachment portion 344 on the metal interconnects 340 extends beyond the surface 332 of the dielectric layer 326. The metal interconnects 340 have an overall thickness in a range from approximately 35um to 65um.

At 226, the second photoresist material layer 336 is removed via a second stripping process resulting in the configuration of FIG. 3N. At 228, the configuration of FIG. 3N undergoes a second (e.g., chemical etching) etching process 460 to remove any exposed portions of the fourth metal layer 334, 335 resulting in the configuration of FIG. 3O. The second etching process 460 uses an acid-based product (e.g., hydrofluoric acid) to remove the exposed portions of the fourth metal layer 334, 335. Once again, however, the multi-layer metal stack 316, 317, 322, 324 protects the wire bond contact pads 308 from the acid-based product during the second etching process 460. Thus, the multi-layer metal stack 316, 317, 322, 324 is a protective element configured to protect each of the wire bond contact pads 308 from the second etching process 460.

At 230, solder interconnects (e.g., solder balls) 346 are deposited (e.g., via electroplating or solder ball attach) on each attachment portion 344 of the metal interconnects 340 resulting in a die assembly 348 illustrated in the configuration of FIG. 3P. At 232, the die assembly 348 is attached to a leadframe 350 resulting in the configuration of FIG. 3Q. Specifically, the leadframe 350 includes inner (internal) leads 352 and outer (external) leads 354 and the die assembly 348 attaches to the inner leads 352 via the solder interconnects 346. At 234, wire bonds 356 are indirectly attached to the wire bond contact pads 308 via the multi-layer metal stack 316, 317, 322, 324 resulting in the configuration of FIG. 3R. Although not shown for simplicity, the wire bonds 356 attach to one or more other dies (e.g., controller die) in the electronic device and/or to the leadframe 350. The presence of the multi-layer metal stack 316, 317, 322, 324 ensures that the wire bond contact pads 308 are protected and undamaged during the first and second etching process. Thus, the wire bonds 356 can be indirectly attached wire bond contact pads 308 via the multi-layer metal stack 316, 317, 322, 324 without compromising performance of the electronic device.

At 236, a heat sink 358 is attached to a second surface 360 of the substrate 302 resulting in the configuration of FIG. 3S. At 238, a mold compound 362 is formed over the die assembly 348, the inner leads 352, and the wire bonds 356. Specifically, the mold compound 362 encapsulates the substrate 302, the die 304 including the contact pads 308, 310, the multi-layer metal stack 316, 317, 322, 324, the dielectric layer 326, the metal interconnects 340, the solder interconnects 346, the inner leads 352, and the wire bonds 356. A surface (exposed surface) 364 of the heat sink 358 is exposed and substantially flush with a surface 366 of the mold compound 362. Thus, the mold compound 362 covers all but one surface of the heat sink 358, where the one surface is the exposed surface 364, where the exposed surface 364 faces away from the die 304. The exposed surface 364 of the heat sink 358 attaches to an external electrical/electronic device (e.g., heat sink) to dissipate heat away from the electronic device.

Described above are examples of the subject disclosure. It is, of course, not possible to describe every conceivable combination of components or methodologies for purposes of describing the subject disclosure, but one of ordinary skill in the art may recognize that many further combinations and permutations of the subject disclosure are possible. Accordingly, the subject disclosure is intended to embrace all such alterations, modifications and variations that fall within the spirit and scope of the appended claims. In addition, where the disclosure or claims recite “a,” “an,” “a first,” or “another” element, or the equivalent thereof, it should be interpreted to include one or more than one such element, neither requiring nor excluding two or more such elements. Furthermore, to the extent that the term “includes” is used in either the detailed description or the claims, such term is intended to be inclusive in a manner similar to the term “comprising” as “comprising” is interpreted when employed as a transitional word in a claim. Finally, the term “based on” is interpreted to mean based at least in part.

What is claimed is:

1. An electronic device comprising:
a leadframe;
a die assembly attached to the leadframe, the die assembly including contact pads and a protective element disposed on one or more of the contact pads;
a wire bond attached from the protective element to one or more other electronic components in the electronic device; and
a mold compound formed over the die assembly.

2. The electronic device of claim 1, wherein the protective element is a multi-layer metal stack comprising a first layer disposed on the one or more of the contact pads, a second layer disposed on the first layer, and a third layer disposed on the second layer.

3. The electronic device of claim 2, wherein the first layer is comprised of a titanium sub-layer and copper sub-layer, the second layer is comprised of nickel, and the third layer is comprised of palladium.

4. The electronic device of claim 1, wherein the one or more of the contact pads comprise wire bond contact pads and interconnect contact pads.

5. The electronic device of claim 4, wherein the protective element is disposed on the wire bond contact pads.

6. The electronic device of claim 5, wherein the protective element is a multi-layer metal stack comprising a first layer disposed on the wire bond contact pads, a second layer disposed on the first layer, and a third layer disposed on the second layer.

7. The electronic device of claim 6, wherein the first layer is comprised of a titanium sub-layer and copper a sub-layer, the second layer is comprised of nickel, and the third layer is comprised of palladium.

8. The electronic device of claim 1 further comprising a heat sink attached to the die assembly opposite that of the leadframe.

9. The electronic device of claim 8, wherein the mold compound covers all but one surface of the heat sink, where the one surface faces away from the die assembly.

10. An electronic device comprising:
a substrate;
a die disposed on a first surface of the substrate, the die including contact pads embedded in an active surface of the die;
a protective element disposed on one or more of the contact pads;
interconnects disposed on one or more different contact pads of the contact pads;
a dielectric layer disposed on the active surface of the die;
a wire bond attached from the protective element to one or more other electronic components in the electronic device;
a leadframe attached to the interconnects; and
a mold compound formed over the die.

11. The electronic device of claim 10, wherein the protective element is a multi-layer metal stack comprising a first layer disposed on the one or more contact pads, a second layer disposed on the first layer, and a third layer disposed on the second layer.

12. The electronic device of claim 11, wherein the first layer is comprised of a titanium sub-layer and a copper sub-layer, the second layer is comprised of nickel, and the third layer is comprised of palladium.

13. The electronic device of claim 10, wherein the one or more of the contact pads comprise wire bond contact pads and interconnect contact pads.

14. The electronic device of claim 13, wherein the protective element is disposed on the wire bond contact pads.

15. The electronic device of claim 14, wherein the protective element is a multi-layer metal stack comprising a first layer disposed on the wire bond contact pads, a second layer disposed on the first layer, and a third layer disposed on the second layer.

16. The electronic device of claim 15, wherein the first layer is comprised of a titanium sub-layer and a copper sub-layer, the second layer is comprised of nickel, and the third layer is comprised of palladium.

17. The electronic device of claim 10 further comprising a heat sink attached to a second surface of the substrate.

18. The electronic device of claim 17, wherein the mold compound covers all but one surface of the heat sink, where the one surface faces away from the die.

19. A method comprising:
attaching a die to a first surface of a substrate, the die having an active surface and contact pads embedded in the active surface of the die;
depositing a protective element on one or more of the contact pads;
depositing a dielectric layer on the active surface of the die;
depositing a seed layer on the dielectric layer;
performing an etching process to remove the seed layer on unwanted portions of the dielectric layer;
depositing interconnects to one or more different contact pads of the contact pads;
attaching a leadframe to the interconnects; and
forming a mold compound over the die.

20. The method of claim 19, wherein depositing a protective element on one or more of the contact pads includes depositing a first layer on the active surface of the die, depositing a second layer on the first layer over the one or more contact pads, and depositing a third layer on the second layer.

21. The method of claim 20, wherein depositing a first layer on the active side of the die includes depositing a first sub-layer on the active side of the die and depositing a second sub-layer on the first sub-layer.

22. The method of claim 21, wherein the etching process is a second etching process, and wherein prior to depositing a dielectric layer on the active surface of the die, the method further comprising performing a first etching process to remove unwanted portions of the first layer from the active side of the die.

23. The method of claim 22, wherein prior to forming a mold compound over the die, the method further comprising attaching wire bonds from the protective element to one or more other dies and/or the leadframe.

24. The method of claim 23, wherein prior to forming a mold compound over the die, the method further comprising attaching a heat sink to a second surface of the substrate.

25. The method of claim 24, wherein the first sub-layer of the first layer is comprised of titanium, the second sub-layer of the first layer is comprised of copper, the second layer is comprised of nickel, and the third layer is comprised of palladium.
